(19) United States
(12) Patent Application Publication
(10) Pub. No.: US 2009/0108269 A1
(43) Pub. Date: Apr. 30, 2009

(54) ILLUMINATION DEVICE HAVING ONE OR MORE LUMIPHORS, AND METHODS OF FABRICATING SAME

(75) Inventors: Gerald H. NEGLEY, Durham, NC (US); Antony Paul Van De Ven, Hong Kong SAR (CN)

Correspondence Address: BURR & BROWN, PO BOX 7068, SYRACUSE, NY, 13261-7068, US

(73) Assignee: LED Lighting Fixtures, Inc., Morrisville, NC (US)

(21) Appl. No.: 12/017,676

(22) Filed: Jan. 22, 2008

Related U.S. Application Data
(60) Provisional application No. 60/982,900, filed on Oct. 26, 2007.

(51) Int. Cl. H01L 33/00

(52) U.S. Cl. 257/88; 257/98; 438/29; 438/16; 257/E33.061

(57) ABSTRACT

A light emitter comprising a monolithic die comprising at least one solid state light emitting device and at least a first lumiphor covering part of a light emission region of the die. In some embodiments, at least a second lumiphor is provided on the die. The first lumiphor can be part of a first pattern of lumiphors, and/or the second lumiphor can be part of a second pattern of lumiphors. The first and second lumiphors can differ in luminescent material, size, shape and/or concentration of luminescent material. The lumiphors can overlap completely, partially, or not at all. Some embodiments comprise an electrical interconnection to electrically connect respective solid state light emitting devices. Also, a light emitter comprising unit cells each comprising a group of light emitting devices and at least one lumiphor. Methods of fabricating light emitters comprise selectively applying at least one lumiphor to a monolithic die.

### CROSS-REFERENCE TO RELATED APPLICATIONS

This application claims the benefit of U.S. Provisional Patent Application No. 60/982,900, filed Oct. 26, 2007, the entirety of which is incorporated herein by reference.

### FIELD OF THE INVENTION(S)

The present inventive subject matter relates to light emitters and, more particularly, to light emitters suitable for use in lighting applications.

### BACKGROUND OF THE INVENTION(S)

Light emitting diode devices that utilize a phosphor to convert light from one wavelength to another are well known. For example, blue light emitting diode devices with a yellow phosphor, such as YAG:Ce, are utilized to create white light. Such light, however, typically has a relatively low color rendering index (CRI) and a relatively high correlated color temperature (CCT). As the CCT of the light is reduced to produce “warm white” light, e.g. a CCT of 3500K, the efficiency of the light emitting diode device/phosphor system is typically reduced. This is the case because of Stokes losses and because warm white light emitting diode devices typically use multiple phosphors and there is some absorption of the output of one phosphor by the other (or others). Lower efficiency also may be the result of lower quantum efficiency in the additional phosphor. For example, a yellow phosphor, such as a YAG phosphor, typically has a relatively high quantum efficiency in converting light from blue wavelengths to yellow wavelengths. In contrast, a red phosphor will typically be less efficient in the conversion. Thus, warm white light emitters which include light emitting diode devices tend to be less efficient than cooler color temperature white light emitters which include light emitting diode devices.

In addition to efforts to improve the production of white light from light emitting diode devices, various efforts have been directed at improving light emitting diode devices by providing larger devices or interconnected devices. For example:

U.S. Pat. No. 6,635,503 describes cluster packaging of light emitting diode devices;

United States Patent Application Publication No. 2003/0089918 describes broad spectrum light emitting devices and methods and systems for fabricating broad spectrum light emitting devices;

U.S. Pat. No. 6,547,249 describes monolithic series/parallel light emitting diode device arrays formed on highly resistive substrates;

U.S. Pat. No. 7,009,199 describes electronic devices having a header and anti-parallel connected light emitting diodes for producing light from AC current;

U.S. Pat. No. 6,885,035 describes multi-chip semiconductor light emitting diode device assemblies;

U.S. Pat. Nos. 6,957,899, 7,213,942 and 7,221,044 each describe single chip integrated light emitting diode devices adapted for direct use with a high AC or DC voltage;

United States Patent Application Publication No 2005/0253151 describes a light emitting device operating on a high drive voltage and a small drive current;

Japanese Patent Publication No. 2001-156331 describes a plurality of nitride semiconductor layers formed on the same substrate, where the layers are electrically separated from each other and each nitride semiconductor layer is electrically connected with a conductive wire;

Japanese Patent Publication No. 2001-307506 describes two or more light emitting diode devices being formed on the same semiconductor substrate; and

United States Patent Application Publication No. 2007/0202623 describes a wafer level package for very small footprint and low profile white light emitting diode devices.

The expression “light emitting diode device” is used herein to refer to the basic semiconductor diode structure (i.e., the chip). The commonly recognized and commercially available “LED” that is sold (for example) in electronics stores typically represents a “packaged” device made up of a number of parts. These packaged devices typically include a semiconductor based light emitting diode device such as (but not limited to) those described in U.S. Pat. Nos. 4,918,487; 5,631,190; and 5,912,477; various wire connections, and a package that encapsulates the light emitting diode device.

Despite these advances in light emitters which include light emitting diode devices, improvements are still needed in light emitters which include light emitting diode devices and techniques for producing white or other colored light from light emitting diode devices.

### SUMMARY OF THE INVENTION(S)

Embodiments of the present inventive subject matter provide light emitters with selectively applied lumiphor(s) on a die. The expression “die”, as used herein, refers to an element which comprises at least one light emitting device (e.g., at least one light emitting diode device); for example, a “die” can be a substrate with a single light emitting device mounted thereon or a substrate with plural light emitting devices mounted thereon (and a “substrate” can refer to any structure or structures which provide one or more surfaces on which such light emitting devices can be positioned).

In a first aspect of the present inventive subject matter, there is provided a light emitter, comprising:

a monolithic die comprising at least one solid state light emitting device; and

at least a first lumiphor (or a pattern of first lumiphors) on the die, the first lumiphor (or pattern of first lumiphors) covering less than all of a light emission region of the monolithic die such that a first portion of light emitted by the at least one solid state light emitting device is directed into the first lumiphor (or pattern of first lumiphors) and a second portion of light emitted by the at least one solid state light emitting device is not directed into the first lumiphor (or pattern of first lumiphors).

As discussed below, the present inventive subject matter encompasses light emitters which each comprise a die having one or more lumiphors and/or lumiphor patterns applied to any number of one or more surfaces thereof, for example, on a top surface, on a bottom surface, on both top and bottom surfaces, or generally on any number of its surfaces (e.g., in the case of a die having six sides, e.g., a cube-shaped die, one or more lumiphors can be applied to any number of one to six of its sides).

In some embodiments according to the first aspect of the present inventive subject matter, the light emitter further comprises:

at least a second lumiphor (or a pattern of second lumiphors) on the die, the second lumiphor (or pattern of second lumiphors) being substantially non-overlapping with the first lumiphor (or pattern of first lumiphors) such that the first portion of light is not directed into the second lumiphor (or pattern of second lumiphors).

In some of such embodiments, the second portion of light emitted by the at least one solid state light emitting device is directed into the second lumiphor (or pattern of second lumiphors).

In some of such embodiments, a third portion of light emitted by the at least one solid state light emitting device is not directed into the first lumiphor (or the first pattern of lumiphors) or into the second lumiphor (or the second pattern of lumiphors).

In some embodiments according to the first aspect of the present inventive subject matter, the light emitter further comprises:

at least a second lumiphor (or a pattern of second lumiphors) on the die, at least a portion of the second lumiphor overlapping at least a portion of the first lumiphor (or at least one of the first pattern of lumiphors), or at least a portion of at least one of the second lumiphors in the pattern of second lumiphors overlaps at least a portion the first lumiphor or at least a portion of at least one of the first pattern of lumiphors).

In some embodiments according to the first aspect of the present inventive subject matter, the at least one solid state light emitting device consists of a single solid state light emitting device.

In some embodiments according to the first aspect of the present inventive subject matter, the at least one solid state light emitting device comprises a plurality of solid state light emitting devices on a common substrate.

In some embodiments according to the first aspect of the present inventive subject matter, the at least one solid state light emitting device comprises a single solid state light emitting device which is a light emitting diode device.

In some embodiments according to the first aspect of the present inventive subject matter, the at least one solid state light emitting device comprises a plurality of solid state light emitting devices, at least one of which is a light emitting diode device.

In some embodiments according to the present inventive subject matter in which there are a plurality of lumiphors, the lumiphors can all be similar to each other, or one or more of the lumiphors can differ from other lumiphors (or from another lumiphor) in its/their respective luminescent material(s), in its/their respective lumiphor concentrations (i.e., amount of luminescent material(s) per unit surface area or unit volume), in its/their respective shapes, and/or in its/their respective sizes. To illustrate, a representative embodiment of a light emitter according to the present inventive subject matter can comprise a die, a first pattern of lumiphors, a second pattern of lumiphors, a third pattern of lumiphors, a fourth pattern of lumiphors, a fifth pattern of lumiphors, and a sixth pattern of lumiphors, wherein:
the first pattern of lumiphors consists of lumiphors which each contain a first luminescent material in a first shape of a first size and in a first concentration,
the second pattern of lumiphors consists of lumiphors which each contain the first luminescent material in the first shape of the first size and in a second concentration,
the third pattern of lumiphors consists of lumiphors which each contain the first luminescent material in the first shape of a second size and in the first concentration,
the fourth pattern of lumiphors consists of lumiphors which each contain the first luminescent material in a second shape of the first size and in the first concentration,
the fifth pattern of lumiphors consists of lumiphors which each contain a second luminescent material in the first shape of the first size and in the first concentration, and
the sixth pattern of lumiphors consists of lumiphors which each contain a third luminescent material in a third shape of a third size and in a third concentration.
   To further illustrate, a second representative embodiment of a light emitter according to the present inventive subject matter can comprise a die, a first pattern of lumiphors, a second pattern of lumiphors and a third pattern of lumiphors, wherein:
the first pattern of lumiphors consists of lumiphors which each contain a first luminescent material (e.g., which emits greenish-yellowish light, such as YAG) in a first shape of a first size and in a first concentration,
the second pattern of lumiphors consists of lumiphors which each contain the first luminescent material in the first shape of the first size and in a second concentration,
the third pattern of lumiphors consists of lumiphors which each contain a second luminescent material (e.g., which emits red light) in the first shape of the first size and in a second concentration.

In a second aspect of the present inventive subject matter, there is provided a light emitter comprising:

a monolithic die comprising a plurality of solid state light emitting devices on a common substrate;

a first lumiphor on a first group of the plurality of solid state light emitting devices, the first group being less than all of the plurality of solid state light emitting devices; and

an electrical interconnection to electrically connect respective ones of the plurality of solid state light emitting devices.

In some embodiments according to the second aspect of the present inventive subject matter, the electrical interconnection connects the plurality of solid state light emitting devices into an array of serially-connected subsets of parallel-connected solid state light emitting devices (i.e., solid state light emitting devices in the plurality of unit cells are electrically connected in an array of serially-connected subsets of solid state light emitting devices, each of the subsets comprising a plurality of solid state light emitting diodes that are electrically connected in parallel).

In some embodiments according to the second aspect of the present inventive subject matter, the light emitter further comprises a second lumiphor on a second group of the plurality of solid state light emitting devices, the second group of solid state light emitting devices and the first group of solid state light emitting devices being mutually exclusive. In some embodiments according to the second aspect of the present inventive subject matter, the second group and the first group together comprise all of the plurality of solid state light emitting devices on the common substrate.

In some embodiments according to the second aspect of the present inventive subject matter, the first group of the plurality of solid state light emitting devices are separately connected as a first array of serially-connected subsets of parallel-connected solid state light emitting devices and remaining ones of the plurality of solid state light emitting devices are connected as at least a second array of serially-connected solid state light emitting devices.

In some embodiments according to the second aspect of the present inventive subject matter, the first group and the second group are electrically connected in parallel.

In some embodiments according to the second aspect of the present inventive subject matter, the first group and the second group are electrically connected so as to be separately controllable.

In some embodiments according to the second aspect of the present inventive subject matter, the first group of solid state light emitting devices are dispersed throughout the plurality of solid state light emitting devices.

In some embodiments according to the second aspect of the present inventive subject matter, the light emitter produces light that is perceived as white when current flows through the plurality of solid state light emitting devices.

In a third aspect of the present inventive subject matter, there is provided a light emitter, comprising:

a monolithic die comprising a plurality of solid state light emitting devices on a common substrate;

an electrical interconnection to electrically connect respective ones of the plurality of solid state light emitting devices; and

a plurality of unit cells, each unit cell comprising a group of the plurality of solid state light emitting devices, each of the unit cells comprising a first lumiphor on less than all of the group of solid state light emitting devices in the unit cell.

In some embodiments according to the third aspect of the present inventive subject matter, each of the unit cells further comprises a second lumiphor, different from the first lumiphor, on solid state light emitting devices in the unit cell other than solid state light emitting devices on which the first lumiphor is provided.

In some embodiments according to the third aspect of the present inventive subject matter, each of the unit cells further comprises a third lumiphor, different from the first and the second lumiphors, on solid state light emitting devices in the unit cell other than solid state light emitting devices on which the first lumiphor is provided or solid state light emitting devices on which the second lumiphor is provided.

In some embodiments according to the third aspect of the present inventive subject matter, solid state light emitting devices in the plurality of unit cells are electrically connected in an array of serially-connected subsets of solid state light emitting devices, each of the subsets comprising a plurality of solid state light emitting diodes that are electrically connected in parallel.

In some embodiments according to the third aspect of the present inventive subject matter, solid state light emitting devices on which the first phosphor is provided are electrically connected in parallel in serially-connected subsets with solid state light emitting devices on which the first phosphor is not provided.

In some embodiments according to the third aspect of the present inventive subject matter, light produced by the light emitter is perceived as white light.

In a fourth aspect of the present inventive subject matter, there is provided a method of fabricating a light emitter, comprising:

selectively applying at least one lumiphor to a monolithic die comprising a plurality of solid state light emitting devices, so as to cover only a portion of the die.

In some embodiments according to the fourth aspect of the present inventive subject matter, selectively applying at least one lumiphor comprises selectively applying a plurality of lumiphors in substantially non-overlapping portions of the die.

In some embodiments according to the fourth aspect of the present inventive subject matter, at least one portion of the die does not have a lumiphor thereon.

In a fifth aspect of the present inventive subject matter, there is provided a method of fabricating a light emitter, comprising:

selectively applying at least one lumiphor on selected ones of a plurality of solid state light emitting devices on a common substrate, the selected ones comprising less than all of the plurality of solid state light emitting devices.

In some embodiments according to the fifth aspect of the present inventive subject matter, selectively applying at least one lumiphor comprises:

applying a first lumiphor on a first group of the plurality of solid state light emitting devices; and

applying a second lumiphor on a second group of the plurality of solid state light emitting devices, the second group and the first group being mutually exclusive.

In some embodiments according to the fifth aspect of the present inventive subject matter, selectively applying comprises selectively applying a plurality of lumiphors in a repeating pattern of unit cells of lumiphors on the plurality of solid state light emitting devices, the unit cells including at least one solid state light emitting device on which each of the plurality of lumiphors is provided.

In some embodiments according to the fifth aspect of the present inventive subject matter, the method further comprises electrically connecting the plurality of solid state light emitting devices in an array of serially-connected subsets of parallel-connected solid state light emitting devices.

In a sixth aspect of the present inventive subject matter, there is provided a light emitter, comprising:

a monolithic die comprising at least one solid state light emitting device;

a first lumiphor (or a pattern of first lumiphors) on the die; and

a second lumiphor (or a pattern of second lumiphors) on the die,

wherein:
a first portion of light emitted by the at least one solid state light emitting device passes through both the first lumiphor and the second lumiphor, and
a second portion of light emitted by the at least one solid state light emitting device passes through the first lumiphor and does not pass through the second lumiphor.

In a seventh aspect of the present inventive subject matter, there is provided a method of fabricating a light emitter, comprising:

selectively applying at least a first lumiphor (or a pattern of first lumiphors) on a monolithic die comprising at least one solid state light emitting device, the first lumiphor (or pattern of first lumiphors) covering less than all of a light emission region of the monolithic die, to form an initial emitter;

measuring a light output from the initial emitter (e.g., measuring the color of light emitted); and

based on the measurement, selectively applying at least a second lumiphor (or a pattern of second lumiphors) on the monolithic die to form the light emitter.

### DESCRIPTION OF THE DRAWINGS

FIG. 1 is a top plan view of a light emitter having multiple light emitting diode devices that are mechanically connected by a common substrate and which have selectively applied phosphors.

FIG. 2 is a top plan view of a light emitter having multiple light emitting diode devices that are mechanically connected by a common substrate and which have selectively applied phosphors.

FIGS. 3A and 3B are top plan views of a light emitter having multiple light emitting diode devices that are mechanically connected by a common substrate and which have selectively applied phosphors.

FIG. 4 is a top plan view of a light emitter having multiple light emitting diode devices that are mechanically connected by a common substrate and which have selectively applied phosphors.

FIG. 5 is a circuit diagram of a possible interconnection of diodes, such as illustrated in FIGS. 1 through 4.

FIG. 6 is a circuit diagram of a possible alternative interconnection of diodes, such as illustrated in FIGS. 1 through 4.

FIG. 7 is a circuit diagram of a possible additional alternative interconnection of diodes, such as illustrated in FIGS. 1 through 4.

FIG. 8 is a flowchart illustrating fabrication steps for providing light emitters, such as those illustrated in FIGS. 1 through 4.

FIG. 9 is a cross-sectional schematic diagram of a combination of selectively applied phosphors and submount provided light emitting diode devices to provide a monolithic light source.

FIG. 10 is a top plan view of a light emitter having a single solid state light emitting device which has selectively applied phosphors.

FIG. 11 is a top plan view of a light emitter having a die which has phosphors applied thereon.

### DETAILED DESCRIPTION OF THE INVENTIVE SUBJECT MATTER

The present inventive subject matter now will be described more fully hereinafter with reference to the accompanying drawings, in which embodiments of the inventive subject matter are shown. However, this inventive subject matter should not be construed as limited to the embodiments set forth herein. Rather, these embodiments are provided so that this disclosure will be thorough and complete, and will fully convey the scope of the inventive subject matter to those skilled in the art. Like numbers refer to like elements throughout. As used herein the term “and/or” includes any and all combinations of one or more of the associated listed items.

The terminology used herein is for the purpose of describing particular embodiments only and is not intended to be limiting of the inventive subject matter. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As noted above, the various aspects of the present inventive subject matter include various combinations of electronic components (transformers, switches, diodes, capacitors, transistors, etc.). Persons skilled in the art are familiar with and have access to a wide variety of such components, and any of such components can be used in making the devices according to the present inventive subject matter. In addition, persons skilled in the art are able to select suitable components from among the various choices based on requirements of the loads and the selection of other components in the circuitry.

A statement herein that two components in a device are “electrically connected,” means that there are no components electrically between the components, the insertion of which materially affect the function or functions provided by the device. For example, two components can be referred to as being electrically connected, even though they may have a small resistor between them which does not materially affect the function or functions provided by the device (indeed, a wire connecting two components can be thought of as a small resistor); likewise, two components can be referred to as being electrically connected, even though they may have an additional electrical component between them which allows the device to perform an additional function, while not materially affecting the function or functions provided by a device which is identical except for not including the additional component; similarly, two components which are directly connected to each other, or which are directly connected to opposite ends of a wire or a trace on a circuit board or another medium, are electrically connected.

Although the terms “first”, “second”, etc. may be used herein to describe various elements, components, regions, layers, sections and/or parameters, these elements, components, regions, layers, sections and/or parameters should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive subject matter.

Embodiments in accordance with the present inventive subject matter are described herein with reference to cross-sectional (and/or plan view) illustrations that are schematic illustrations of idealized embodiments of the present inventive subject matter. As such, variations from the shapes of the illustrations as a result, for example, of manufacturing techniques and/or tolerances, are to be expected. Thus, embodiments of the present inventive subject matter should not be construed as limited to the particular shapes of regions illustrated herein but are to include deviations in shapes that result, for example, from manufacturing. For example, an implanted region illustrated or described as a rectangle will, typically, have rounded or curved features. Thus, the regions illustrated in the figures are schematic in nature and their shapes are not intended to illustrate the precise shape of a region of a device and are not intended to limit the scope of the present inventive subject matter.

Unless otherwise defined, all terms (including technical and scientific terms) used herein have the same meaning as commonly understood by one of ordinary skill in the art to which this inventive subject matter belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

Embodiments of the present inventive subject matter may be utilized with any suitable solid state light emitting device structure. Exemplary embodiments are described with reference to an InGaN multi-quantum well light emitting diode device structure, although any other suitable solid state light emitting device structures can be employed, e.g., ZnO, ZnTe or any other Group III-Group V and/or Group II-Group VI combination, any binary, ternary or quaternary combination of aluminum, indium, gallium and phosphorus, any binary, ternary or quaternary combination of aluminum, indium, gallium and nitrogen, any binary, ternary or quaternary combination of aluminum, gallium, indium and arsenic, or the like may be used, if desired. Thus, any solid state light emitting device structure that provides a sufficiently large area on which multiple separate areas of luminous material may be formed or transferred as described herein may be suitable for use in embodiments of the present inventive subject matter.

A wide variety of such solid state light emitting devices may be utilized in accordance with the teachings herein. Such solid state light emitting devices include inorganic and organic light emitters, a variety of each of which are well-known in the art (and therefore it is not necessary to describe in detail such devices, and/or the materials out of which such devices are made). Furthermore, the output emission wavelengths of such light emitting devices may be anywhere in the range of from the visible spectrum to near ultraviolet to ultraviolet.

Where more than one solid state light emitter devices are present, the respective solid state light emitter devices can be similar to one another, different from one another or any combination.

Representative examples of suitable solid state light emitting devices are described in:

(1) U.S. Patent Application No. 60/753,138, filed on Dec. 22, 2005, entitled “Lighting Device” (inventor: Gerald H. Negley; attorney docket number 931_{—}003 PRO) and U.S. patent application Ser. No. 11/614,180, filed Dec. 21, 2006, the entireties of which are hereby incorporated by reference;

(2) U.S. Patent Application No. 60/794,379, filed on Apr. 24, 2006, entitled “Shifting Spectral Content in LEDs by Spatially Separating Lumiphor Films” (inventors: Gerald H. Negley and Antony Paul van de Ven; attorney docket number 931_{—}006 PRO) and U.S. patent application Ser. No. 11/624,811, filed Jan. 19, 2007, the entireties of which are hereby incorporated by reference;

(3) U.S. Patent Application No. 60/808,702, filed on May 26, 2006, entitled “Lighting Device” (inventors: Gerald H. Negley and Antony Paul van de Ven; attorney docket number 931_{—}009 PRO) and U.S. patent application Ser. No. 11/751,982, filed May 22, 2007, the entireties of which are hereby incorporated by reference;

(4) U.S. Patent Application No. 60/808,925, filed on May 26, 2006, entitled “Solid State Light Emitting Device and Method of Making Same” (inventors: Gerald H. Negley and Neal Hunter; attorney docket number 931_{—}010 PRO) and U.S. patent application Ser. No. 11/753,103, filed May 24, 2007, the entireties of which are hereby incorporated by reference;

(5) U.S. Patent Application No. 60/802,697, filed on May 23, 2006, entitled “Lighting Device and Method of Making” (inventor: Gerald H. Negley; attorney docket number 931_{—}011 PRO) and U.S. patent application Ser. No. 11/751,990, filed May 22, 2007, the entireties of which are hereby incorporated by reference;

(6) U.S. Patent Application No. 60/839,453, filed on Aug. 23, 2006, entitled “LIGHTING DEVICE AND LIGHTING METHOD” (inventors: Antony Paul van de Ven and Gerald H. Negley; attorney docket number 931_{—}034 PRO) and U.S. patent application Ser. No. 11/843,243, filed Aug. 22, 2007, the entireties of which are hereby incorporated by reference;

(7) U.S. Patent Application No. 60/857,305, filed on Nov. 7, 2006, entitled “LIGHTING DEVICE AND LIGHTING METHOD” (inventors: Antony Paul van de Ven and Gerald H. Negley; attorney docket number 931_{—}027 PRO and U.S. patent application Ser. No. 11/936,163, filed Nov. 7, 2007, the entireties of which are hereby incorporated by reference;

(8) U.S. Patent Application No. 60/851,230, filed on Oct. 12, 2006, entitled “LIGHTING DEVICE AND METHOD OF MAKING SAME” (inventor: Gerald H. Negley; attorney docket number 931_{—}041 PRO) and U.S. patent application Ser. No. 11/870,679, filed Oct. 11, 2007, the entireties of which are hereby incorporated by reference.

While embodiments of the present inventive subject matter are described below with reference to light emitting diode devices, other solid state light emitting devices may also be utilized in alternative embodiments of the present inventive subject matter. For example, embodiments of the present inventive subject matter may be suitable for use with organic or inorganic light emitting devices which may be provided as a large area device, for example as a monolithic die comprising a collection of individual devices on a semiconductor substrate. Such light emitting devices are collectively referred to herein as “solid state lighting devices.”

Some embodiments of the inventive subject matter use selective deposition of a lumiphor, such as a phosphor, to provide a multiple solid state light emitting device light emitter where at least some of the light emitting diode devices are mechanically connected on a common substrate on which the light emitting diode devices were fabricated. As used herein, the term “solid state light emitting device” refers to an individual solid state light emitting device structure that may be separately electrically connected to other light emitting device structures in either a series and/or parallel configuration. In some embodiments according to the present inventive subject matter, multiple solid state light emitting devices remain mechanically connected to each other by a common substrate and are not singulated but provide a monolithic structure of multiple independently electrically connectable solid state light emitting device structures. Such monolithic multiple solid state light emitting device light emitters are described, for example, in:

(1) commonly assigned and concurrently filed U.S. patent application Ser. No. ______ entitled FAULT TOLERANT LIGHT EMITTERS, SYSTEMS INCORPORATING FAULT TOLERANT LIGHT EMITTERS AND METHODS OF FABRICATING FAULT TOLERANT LIGHT EMITTERS (Attorney Docket No. 931_{—}056 NP; Inventors: Gerald H. Negley and Antony Paul van de Ven), the disclosure of which is incorporated herein by reference as if set forth in its entirety, as well as: U.S. Patent Application No. 60/885,937, filed on Jan. 22, 2007, entitled “HIGH VOLTAGE SOLID STATE LIGHT EMITTER” (inventor: Gerald H. Negley; attorney docket no. 931_{—}056 PRO), U.S. Patent Application No. 60/982,892, filed on Oct. 26, 2007, entitled “FAULT TOLERANT LIGHT EMITTERS, SYSTEMS INCORPORATING FAULT TOLERANT LIGHT EMITTERS AND METHODS OF FABRICATING FAULT TOLERANT LIGHT EMITTERS” (inventors: Gerald H. Negley and Antony Paul van de Ven; attorney docket no. 931_{—}056 PRO2), and U.S. Patent Application No. 60/986,662, filed on Nov. 9, 2007 (attorney docket no. 931_{—}056 PRO3), the entireties of which are hereby incorporated by reference, and/or

(2) commonly assigned and concurrently filed U.S. patent application Ser. No. ______ entitled ILLUMINATION DEVICES USING INTERCONNECTED ARRAYS OF LIGHT EMITTING DEVICES, AND METHODS OF FABRICATING SAME (Attorney Docket No. 931_{—}078 NP; Inventors: Gerald H. Negley and Antony Paul van de Ven), the disclosure of which is incorporated herein by reference as if set forth in its entirety, as well as: U.S. Patent Application No. 60/982,909, filed on Oct. 26, 2007, entitled “ILLUMINATION DEVICES USING EXTERNALLY INTERCONNECTED ARRAYS OF LIGHT EMITTING DEVICES, AND METHODS OF FABRICATING SAME” (inventors: Gerald H. Negley and Antony Paul van de Ven; attorney docket no. 931_{—}078 PRO) and U.S. Patent Application No. 60/986,795, filed Nov. 9, 2007 (attorney docket no. 931_{—}078 PRO2), the entireties of which are hereby incorporated by reference.

While embodiments of the present inventive subject matter are described primarily with reference to monolithic multiple solid state light emitting device light emitters, embodiments of the present inventive subject matter may be utilized in any device that is of sufficient dimensions to provide discrete placement of lumiphors. Thus, the present inventive subject matter should not be construed as limited to the particular multiple solid state light emitting device light emitters described herein but may be used with any solid state light emitting device light emitter. The particular minimum dimensions of such a light emitter may depend on the application technology for the lumiphors.

The expression “lumiphor”, as used herein, refers to any luminescent element, i.e., any element which includes a luminescent material.

The lumiphor or lumiphors can individually comprise any luminescent material or combination of luminescent materials, a wide variety of which are known to those skilled in the art. For example, the one or more luminescent materials in any particular lumiphor can be selected from among phosphors, scintillators, day glow tapes, inks which glow in the visible spectrum upon illumination with ultraviolet light, etc. The one or more luminescent materials can be down-converting or up-converting, or can include a combination of both types. For example, the first lumiphor can comprise one or more down-converting luminescent materials.

The (or each of the) lumiphor(s) can, if desired, further comprise one or more highly transmissive (e.g., transparent or substantially transparent, or somewhat diffuse) binder, e.g., made of epoxy, silicone, glass, metal oxide or any other suitable material (for example, in any given lumiphor comprising one or more binder, one or more phosphor can be dispersed within the one or more binder). In general, the thicker the lumiphor, the lower the weight percentage of the phosphor can be, i.e., depending on the overall thickness of the lumiphor, the weight percentage of the phosphor could be generally any value, e.g., from 0.1 weight percent to 100 weight percent (e.g., a lumiphor formed by subjecting pure phosphor to a hot isostatic pressing procedure).

The (or each of the) lumiphor(s) can, independently, further comprise any of a number of well-known additives, e.g., diffusers, scatterers, tints, etc.

Representative examples of suitable lumiphors are described in the patent applications referred to herein and incorporated herein by reference.

Statements herein that regions are each isolated regions of a single monolithic layer (and similar statements), means that (at least) each of the regions include structural features which persons of ordinary skill in the art recognize inherently result from being formed as a single monolithic layer and later being isolated from each other, e.g., by forming one or more trenches, implanting ions, etc., such that electricity cannot be conducted directly between the respective regions.

A statement that two or more elements are “isolated” from each other means that the respective elements are not in direct contact with each other (even though, for example, they might both be in contact with another element).

The expression “monolithic”, when referring to a die which includes only a single solid state light emitting device, indicates that the solid state light emitting device includes at least one layer which is monolithic (and in some cases, all of the layers of the solid state light emitting device are monolithic). The expression “monolithic”, when referring to a die which includes a plurality of solid state light emitting devices, indicates that at least one respective layer of each of the solid state light emitting devices is an isolated region of a monolithic layer (and in some cases, all of the respective layers of the solid state light emitting devices are isolated regions of respective monolithic layers, i.e., in a representative example of such cases, each solid state light emitting device includes a p-type layer and an n-type layer, the respective p-type layers are each isolated regions of a monolithic p-type layer, and the respective n-type layers are each isolated regions of a monolithic n-type layer.

By providing a monolithic light emitter where the same type of underlying light emitter is utilized to excite different, discretely located, lumiphors (as in some embodiments of the present inventive subject matter), environmental impact on an overall system made of such light emitters may be reduced. For example, in conventional systems that utilize different types of light emitting diode devices to generate different colors, these different types of light emitting diode devices may react differently to changes in environmental conditions. Thus, InGaP red light emitting diode devices may be more affected by changes in temperature than InGaN blue light emitting diode devices. In light emitters according to some embodiments of the present inventive subject matter where all the light emitting diode devices are of the same material, the effect of temperature would be the same on all the light emitting diode devices. Thus, there may be no need to compensate for variations in temperature to maintain a color point if the emissions from the phosphors change proportionally with differing excitation light outputs.

Similarly, because the excitation sources are formed from the same general region of a wafer (as in some embodiments according to the present inventive subject matter, e.g., where a plurality of solid state light emitting devices each comprise at least one region which is an isolated region of a first monolithic layer (for example, where the solid state light emitting devices each comprise an n-type layer and a p-type layer, and the n-type layer is an isolated region of a monolithic n-type layer and the p-type layer is an isolated region of a monolithic p-type layer, etc.)), there may be less variability in their electrical and/or photonic characteristics than if discrete devices from different areas of a wafer or from different wafers were interconnected. For example, the output wavelengths of adjacent solid state light emitting devices on the wafer may be more likely to be substantially the same than would be the case from two solid state light emitting devices from different wafers or even from two solid state light emitting devices from remote locations on the same wafer. A similar correlation may be present with Vf.

The expression “excited”, as used herein when referring to a lumiphor, means that at least some electromagnetic radiation (e.g., visible light, UV light or infrared light) is contacting the lumiphor, causing the lumiphor to emit at least some light. The expression “excited” encompasses situations where the lumiphor emits light continuously or intermittently at a rate such that a human eye would perceive it as emitting light continuously, or where a plurality of lumiphors of the same color or different colors are emitting light intermittently and/or alternatingly (with or without overlap in “on” times) in such a way that a human eye would perceive them as emitting light continuously (and, in cases where different colors are emitted, as a mixture of those colors).

The expression “overlap” (or “overlapping”), as used herein, e.g., “at least a portion of the second lumiphor overlapping at least a portion of the first lumiphor” means that the structure that overlaps a second structure can be above, below or to the side of the second structure, and/or that the respective structures or materials can be partially or completely mixed together. For example, the expression “at least a portion of the second lumiphor overlapping at least a portion of the first lumiphor” encompasses situations where the second lumiphor is coated on top of the first lumiphor, where the first lumiphor is coated on top of the second lumiphor, where at least part of the luminescent material in the first lumiphor is mixed with at least part of the lumiphor in the second lumiphor, etc.

Luminous material (also referred to herein as luminescent material), such as a phosphor or phosphors, is applied to the solid state light emitting devices and, in some embodiments, is selectively applied to the solid state light emitting devices. Luminous material may be applied to some or all of the mechanically connected solid state light emitting devices. For example, if the light emitting diode device output light in a UV range, luminous material may be applied to all of the solid state light emitting devices to prevent UV light from escaping the device. If the light emitting diode device outputs light in the blue range of wavelengths, luminous material may be applied to only some of the light emitting diode devices such that blue light that does not pass through a phosphor and light emitted from the excited phosphor are both emitted by the device. Also, in some embodiments, one or more of the solid state light emitting devices are coated with a phosphor but a portion of the light emitted by the solid state light emitting devices passes through the phosphor without being converted (i.e., in such embodiments, not all of the light emitted by the solid state light emitting devices is absorbed by a phosphor, i.e., the phosphor or one of the phosphors).

In some embodiments, interconnections (either on a common substrate or on a submount to which the light emitting diode devices are mounted) electrically connect the mechanically connected solid state light emitting devices to provide a high voltage monolithic light emitter. The light emitter includes a plurality of solid state light emitting devices electrically connected in an array having two or more subsets which each include at least three solid state light emitting devices connected in parallel (see, e.g., U.S. Patent Application Ser. No. 60/986,662 entitled FAULT TOLERANT LIGHT EMITTERS, SYSTEMS INCORPORATING FAULT TOLERANT LIGHT EMITTERS AND METHODS OF FABRICATING FAULT TOLERANT LIGHT EMITTERS, filed Nov. 9, 2007 (Attorney Docket No. 931_{—}056 PRO3; Inventors: Gerald H. Negley and Antony Paul van de Ven). The array electrical interconnection provides for the anodes of solid state light emitting devices in a row to be electrically connected together and the cathodes to be electrically connected to each other and to anodes of solid state light emitting devices in a subsequent row. By electrically connecting the solid state light emitting devices in such an array, the failure of one or more solid state light emitting devices in any subset of the array may be compensated for by the other solid state light emitting devices in the subset. Similarly, by electrically connecting the solid state light emitting devices in an array, failure of one or more solid state light emitting devices may also be compensated for by the other solid state light emitting devices in the array. Preferably, at least two subsets of parallel-connected solid state light emitting devices are included, and in some embodiments, a sufficient number of subsets are included to make the multiple solid state light emitting device light emitter a 50 volt, 100 volt, 150 volt or even 200 volt light emitter. Furthermore, in some embodiments, light emitters of differing respective voltages can be provided on a single common substrate.

The present inventive subject matter provides light emitters in which activation of the light emitter (i.e., supplying electricity to it) activates more than one light emitting device contained in the light emitter, i.e., the light emitters are not arrays of individually addressable light emitting devices (such as in the case of displays and the like).

The light emitters of the present inventive subject matter can be arranged, mounted and supplied with electricity in any desired manner, and can be mounted on any desired housing or fixture. Skilled artisans are familiar with a wide variety of arrangements, mounting schemes and power supplying apparatuses, and any such arrangements, schemes and apparatuses can be employed in connection with the present inventive subject matter.

For example, persons skilled in the art are very familiar with a variety of suitable leadframes, some of which comprise a pair of leads, one of which is integral with a reflective cup which is in contact with a first region of the solid state light emitter chip (i.e., either its anode or its cathode), the other lead being connected to a wire which is connected to a second region of the solid state light emitter chip (either its anode and cathode, whichever is not in the first region of the solid state light emitter chip).

In addition, any desired circuitry can be employed in order to supply energy to the light emitters according to the present inventive subject matter. Representative examples of circuitry which may be used in practicing the present inventive subject matter are described in:

(1) U.S. Patent Application No. 60/752,753, filed on Dec. 21, 2005, entitled “Lighting Device” (inventors: Gerald H. Negley, Antony Paul van de Ven and Neal Hunter; attorney docket number 931_{—}002 PRO) and U.S. patent application Ser. No. 11/613,692, filed Dec. 20, 2006, the entireties of which are hereby incorporated by reference;

(2) U.S. Patent Application No. 60/798,446, filed on May 5, 2006, entitled “Lighting Device” (inventor: Antony Paul van de Ven; attorney docket number 931_{—}008 PRO) and U.S. patent application Ser. No. 11/743,754, filed May 3, 2007, the entireties of which are hereby incorporated by reference;

(3) U.S. Patent Application No. 60/809,959, filed on Jun. 1, 2006, entitled “Lighting Device With Cooling” (inventors: Thomas G. Coleman, Gerald H. Negley and Antony Paul van de Ven attorney docket number 931_{—}007 PRO) and U.S. patent application Ser. No. 11/626,483, filed Jan. 24, 2007, the entireties of which are hereby incorporated by reference;

(4) U.S. Patent Application No. 60/809,595, filed on May 31, 2006, entitled “LIGHTING DEVICE AND METHOD OF LIGHTING” (inventor: Gerald H. Negley; attorney docket number 931_{—}018 PRO) and U.S. patent application Ser. No. 11/755,162, filed May 30, 2007, the entireties of which are hereby incorporated by reference; and

(5) U.S. Patent Application No. 60/844,325, filed on Sep. 13, 2006, entitled “BOOST/FLYBACK POWER SUPPLY TOPOLOGY WITH LOW SIDE MOSFET CURRENT CONTROL” (inventor: Peter Jay Myers; attorney docket number 931_{—}020 PRO), and U.S. patent application Ser. No. 11/854,744, filed Sep. 13, 2007, the entireties of which are hereby incorporated by reference.

The lighting devices of the present inventive subject matter can be electrically connected (or selectively connected) to any desired power source, persons of skill in the art being familiar with a variety of such power sources.

In some embodiments of the present inventive subject matter, the lighting devices further comprise an encapsulant region. Persons of skill in the art are familiar with, and have easy access to, a wide variety of materials which are suitable for use in making an encapsulant region for a packaged LED, and any such materials can, if desired, be employed. For example, two well-known representative classes of materials out of which the encapsulant region can be constructed include epoxies and silicones.

Persons of skill in the art are also familiar with a wide variety of suitable shapes for the encapsulant region, and the encapsulant region(s) in the device according to the present inventive subject matter can be of any such shape. Persons of skill in the art are also familiar with various ways to make a packaged device incorporating the various elements described herein in connection with the present inventive subject matter. Accordingly, further description of materials for use in making the encapsulant region, shapes for the encapsulant region and methods of making the devices described herein is not needed.

The present inventive subject matter encompasses a light emitter comprising a monolithic die having one or more lumiphors and/or lumiphor patterns applied to any number of one or more surfaces thereof, for example, on a top surface, on a bottom surface, on both top and bottom surfaces, or generally on one or more surfaces of a die having any desired number of surfaces.

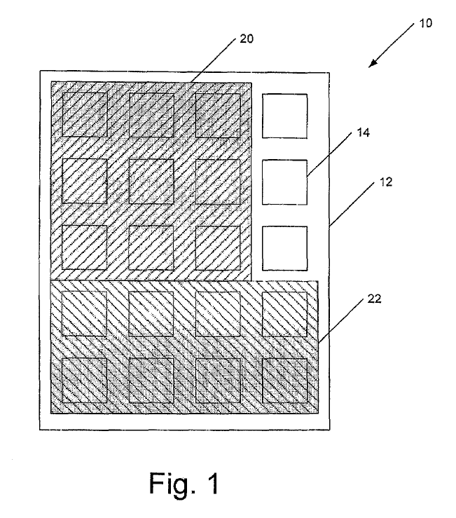

FIGS. 1 through 4 are plan views of a plurality of light emitting diode devices, each with selectively applied lumiphors applied to a single side of the device—alternative embodiments could be provided with respective lumiphors and/or patterns of lumiphors on both (or plural) sides. In FIGS. 1 through 4, the plan view illustrates the side of the device with the lumiphor applied. Thus, as described below, in some embodiments, FIGS. 1 through 4 illustrate the substrate side of the device, while in other embodiments, FIGS. 1 through 4 illustrate the top side or side of the device opposite the substrate. The individual light emitting diode devices may have any desired light emitting diode device configuration, including the configuration and perimeter shape or shapes. For example, the light emitting diode devices may be InGaN, InGaP light emitting diode devices and may be multi-quantum well, single quantum well or other light emitting diode device structure. Likewise, the shape of the devices may be square, rectangular, triangular or other regular or irregular shape. Furthermore, different shapes may be provided in a single monolithic device (see, e.g., commonly assigned and concurrently filed U.S. patent application Ser. No. ______ entitled FAULT TOLERANT LIGHT EMITTERS, SYSTEMS INCORPORATING FAULT TOLERANT LIGHT EMITTERS AND METHODS OF FABRICATING FAULT TOLERANT LIGHT EMITTERS (Attorney Docket No. 931_{—}056 NP; Inventors: Gerald H. Negley and Antony Paul van de Ven), as well as U.S. Patent Application Ser. No. 60/986,662, filed Nov. 9, 2007 (Attorney Docket No, 931_{—}056 PRO3), U.S. Patent Application No. 60/982,892, filed on Oct. 26, 2007 (attorney docket no. 931_{—}056 PRO2) and U.S. Patent Application No. 60/885,937, filed on Jan. 22, 2007, entitled “HIGH VOLTAGE SOLID STATE LIGHT EMITTER” (inventor: Gerald H. Negley; attorney docket no. 931_{—}056 PRO).

As seen in FIGS. 1 through 4, the individual light emitting diode devices remain on the substrate to provide a plurality of separate light emitting diode devices that are physically connected by the common substrate. In some embodiments, the light emitting diode devices are flip-chip mounted such that light is extracted through the substrate. In such a case, the substrate should be substantially transparent. In other embodiments, the light is extracted from the top of the device. For example, the substrate may be sapphire, spinel, semi-insulating or insulating SiC, semi-insulating or insulating Si, semi-insulating or insulating GaN, semi-insulating or insulating ZnO, or semi-insulating or insulating AlN. The substrate material will, typically, be selected based on light emitting diode device material selection and may be selected based on the light extraction path from the device. These differing paths for light through different configuration devices are collectively referred to as “light extraction regions” of the light emitting diode devices. Thus, in some embodiments of the present inventive subject matter, the light extraction region is through the substrate, in other embodiments it is through the “top” of the device, and in other embodiments, light extraction can be from multiple faces of the light emitter, e.g., from both sides.

FIG. 1 illustrates a monolithic light emitter 10 with multiple light emitting diode devices 14 on a common substrate 12. The light extraction regions of individual solid state light emitting devices are covered with a luminous material, such as phosphor. Thus, region 20 is covered with a first phosphor and region 22 is covered with a second phosphor. Thus, light from solid state light emitting devices within the region 20 does not substantially excite the second phosphor in region 22 and, likewise, light from the solid state light emitting devices in region 22 does not substantially excite the first phosphor in region 20. As an example, the light emitting diode devices 14 may emit blue light, the region 20 may be covered with a phosphor that converts some or all of the blue light to green light and the region 22 may be covered with a phosphor that converts some or all of the blue light to red light. Accordingly, the monolithic device 10 would have a green emitting region 20, a red emitting region 22 and a blue emitting region where no phosphor is provided. Accordingly, a monolithic RGB device can be provided.

The number of solid state light emitting devices covered by phosphor can be varied based upon the efficacy of conversion of the phosphor, the sensitivity of the human eye or other observing device to the wavelength(s) output by the phosphor, the spectrum distribution of the phosphor, a desired output hue, the location of the solid state light emitting devices within the monolithic device and/or the interconnection of the diodes within the monolithic device. Furthermore, embodiments of the present inventive subject matter may utilize any suitable luminous material. Phosphors for producing differing colors and for use with various excitation wavelengths are known to those of skill in the art and, therefore, need not be described further herein.

Returning to FIG. 1, as an example of the types of considerations that may be involved in determining the number and which light extraction region of solid state light emitting devices are to be covered with which phosphor, in FIG. 1, the green region 20 is larger than the red region 22 or the uncovered blue solid state light emitting devices. This is because green phosphors may be less efficient at converting blue light to green light than, for example, yellow phosphors may be at converting blue light to yellow light. The red region 22 is smaller than the green region 20 because red phosphors are more efficient than green phosphors. The blue region of uncovered solid state light emitting devices is the smallest because there are no conversion losses from the phosphor. The sizes of these various regions may be adjusted to provide, for example, light that is perceived as white. As used herein, light is perceived as white if it is within eight MacAdam step ellipses of the black body locus on the 1931 CIE chromaticity diagram.

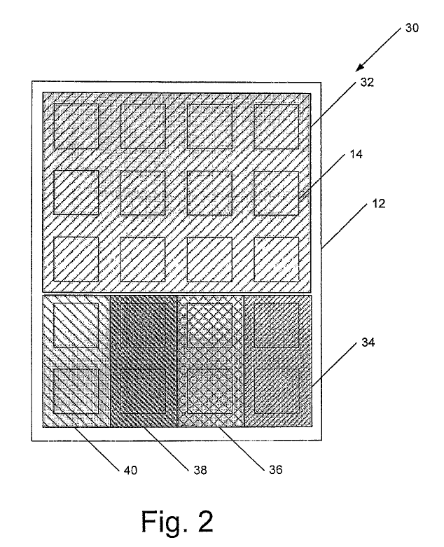

FIG. 2 illustrates a monolithic device 30 with additional different types of phosphors. In the device 30 of FIG. 2, a region of green phosphor 32 is provided with a region of red phosphor 40, a region of cyan phosphor 38, a region of yellow phosphor 36 and a region of blue phosphor or no phosphor 34. The blue region 34 may be uncovered light emitting diode devices for blue light emitting diode devices as the excitation source of the other phosphors or it may be a blue phosphor if, for example, a UV, near UV or violet light source is used as the excitation source. Such a range of colors may, for example, provide increased color gamut for variable color devices and/or improved color rendering in white devices.

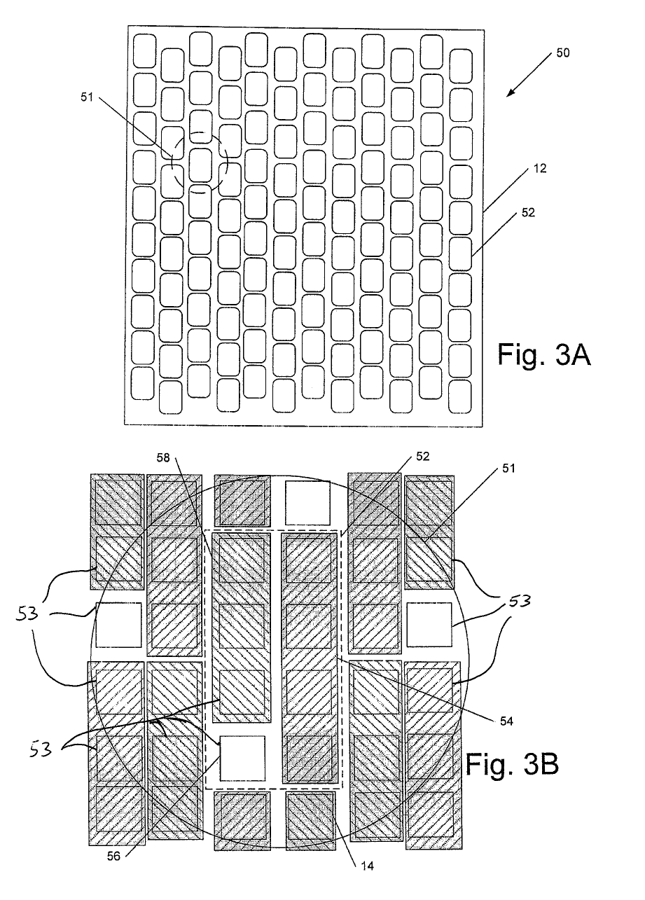

FIGS. 3A and 3B are plan views of a monolithic device 50 having a plurality of repeating multiple phosphor regions 52 or “unit cells.” FIG. 3A is a plan view of an exemplary monolithic device 50 and FIG. 3B is a close-up of a portion 51 of the device 50. In FIG. 3A, a pattern of regions or unit cells, each of which incorporates multiple phosphors, may be provided so as to improve mixing of light from the phosphors and underlying solid state light emitting devices by placing the light sources in close proximity of each other. Thus, as an example, in FIG. 3B each region 52 includes a plurality of solid state light emitting devices 53, a lumiphor 54 which comprises green luminescent material, a lumiphor 58 of red luminescent material, while one of the solid state light emitting devices 53, shown with reference number 56, has no phosphor, to provide red, green and blue colors. Accordingly, the overall device 50 depicted in FIGS. 3A and 3B includes a plurality of first lumiphors 54 in a first pattern and a plurality of second lumiphors 58 in a second pattern. FIG. 3B provides a more accurate representation of the individual regions 52 than FIG. 3A does, i.e., the spacing between different regions 52 is exaggerated in FIG. 3A (which indicates the repetitive nature of the regions 52). In addition, FIG. 3B shows that the relative arrangement of the respective lumiphors 54 and 58 within the regions 52 can differ among the different respective regions 52.

Because the monolithic device 50 may be relatively large, for example, 1, 3 or 5 mm square or more, providing smaller, more closely spaced regions of multiple color phosphors may improve mixing of light from the overall device by the sources of light being in close proximity to each other such that the individual sources blend together as their proximity and size make them below the resolution of the human eye when viewed at a distance. Similarly, even if viewable as discrete light sources, the close proximity may make obscuring the individual light sources easier and, thereby, facilitate providing a light source where the light output appears as a substantially uniform color.

While a particular shape and pattern are illustrated in FIGS. 3A and 3B, any suitable pattern, including pseudo-random patterns, may be utilized. Preferably the pattern is of a size and shape such that it reduces or minimizes the ability of the human eye to detect the pattern.

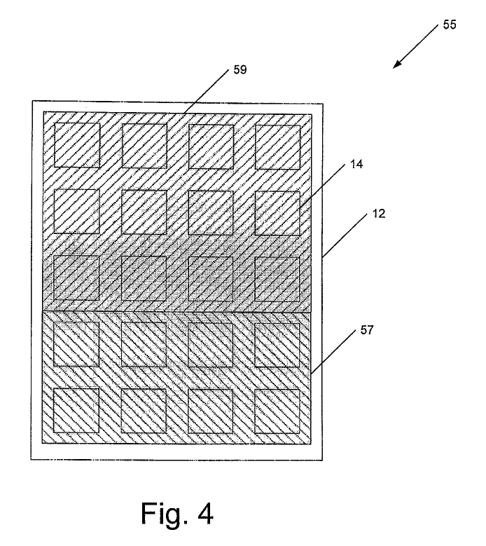

FIG. 4 illustrates a further embodiment of the present inventive subject matter which may be particularly well suited to producing white light as described in U.S. Pat. No. 7,213,940 (“the '940 patent”), the disclosure of which is incorporated herein as if set forth in its entirety. In FIG. 4, the monolithic light emitter 55 includes a phosphor coated region 59 that is a blue light emitting diode device coated with a YAG phosphor to produce yellowish green light falling within the ranges set forth in the '940 patent. A second region 57 includes a red phosphor that converts the blue light from the light emitting diode device to a red color falling within the wavelength range specified in the '940 patent. When combined, the light emitted from the two regions 59, 57, is perceived as white light.

In addition to the pattern illustrated in FIG. 4, a pattern of individual regions of yellowish green emitting regions and red emitting regions may be provided as described above with reference to FIG. 3A. Such a pattern of individual regions may be provided to, for example, improve light mixing and/or reduce the detectability of the component regions as the monolithic device 55 increases in size.

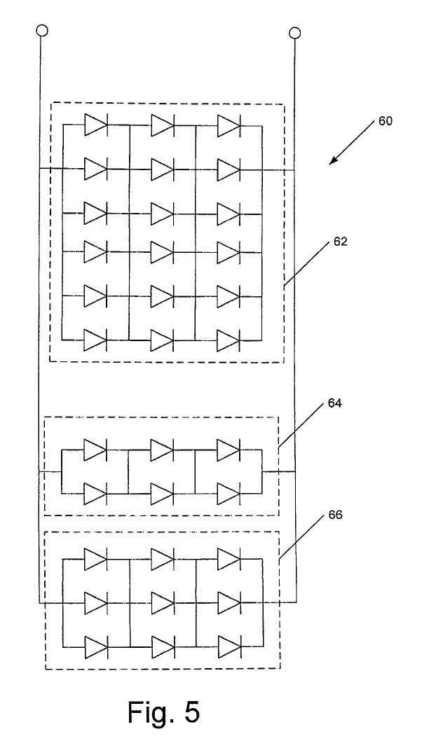

FIGS. 5 through 7 illustrate ways of electrically interconnecting the individual solid state light emitting devices of a monolithic light emitter. As seen in FIG. 5, each color within a light emitter may be electrically connected as sub-arrays of light emitting diode devices that are in both parallel and serial relationship. These sub-arrays may then be connected in parallel such that a two terminal device is provided. Thus, for example, a monolithic light emitter 60 may include three sub-arrays of light emitting diode devices where a first sub-array 62 corresponds to light emitting diode devices with a first phosphor (e.g, green), a second sub-array of light emitting diode devices 64 corresponds to light emitting diode devices with no phosphor (e.g., blue) and a third sub-array of light emitting diode devices 66 corresponds to light emitting diode devices with a second phosphor (e.g, red).

In the case of the circuit of FIG. 5, if one of the light emitting diode devices in a sub-array fails by going open circuit, the other light emitting diode devices in that level of the sub-array will handle the extra current and, at least partially, compensate for the failed light emitting diode device. However, in the case of a light emitting diode device failing by becoming a short circuit, then the voltage across all the sub-arrays will drop and the other sub-arrays may have insufficient voltage to overcome their threshold voltage and the other sub-arrays would turn off, or if the voltage across all the sub-arrays could be maintained then the current through the sub-array with the failure would increase to reach equilibrium. This increase in current may be detrimental to the remaining diodes in the sub-array with the failure and could result in shorter lifetime of these devices. Thus, if an arrangement such as illustrated in FIG. 5 is utilized, a fuse or other self-healing mechanism as described in:
U.S. patent application Ser. No. ______ entitled FAULT TOLERANT LIGHT EMITTERS, SYSTEMS INCORPORATING FAULT TOLERANT LIGHT EMITTERS AND METHODS OF FABRICATING FAULT TOLERANT LIGHT EMITTERS (Attorney Docket No. 931_{—}056 NP; Inventors: Gerald H. Negley and Antony Paul van de Ven), as well as U.S. patent application Ser. No. 60/986,662, filed Nov. 9, 2007 (Attorney Docket No. 931_{—}056 PRO3), U.S. Patent Application No. 60/982,892, filed on Oct. 26, 2007 (attorney docket no. 931_{—}056 PRO2) and U.S. Patent Application No. 60/885,937, filed on Jan. 22, 2007, entitled “HIGH VOLTAGE SOLID STATE LIGHT EMITTER” (inventor: Gerald H. Negley; attorney docket no 931_{—}056 PRO),
   or
commonly assigned and concurrently filed U.S. patent application Ser. No. ______ entitled ILLUMINATION DEVICES USING INTERCONNECTED ARRAYS OF LIGHT EMITTING DEVICES, AND METHODS OF FABRICATING SAME (Attorney Docket No. 931_{—}078 NP; Inventors: Gerald H, Negley and Antony Paul van de Ven), as well as U.S. Patent Application Ser. No. 60/986,795 entitled ILLUMINATION DEVICES USING INTERCONNECTED ARRAYS OF LIGHT EMITTING DEVICES, AND METHODS OF FABRICATING SAME, filed Nov. 9, 2007 (Attorney Docket No. 931_{—}078 PRO2), and U.S. Patent Application No. 60/982,909, filed on Oct. 26, 2007 (attorney docket no. 931_{—}078 PRO),
   may be beneficial

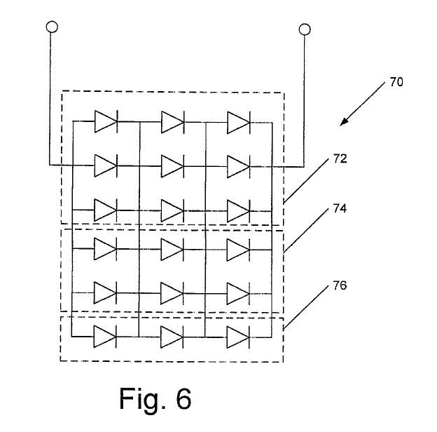

FIG. 6 illustrates an alternative electrical interconnection for the individual solid state light emitting devices of a monolithic light emitter. As seen in FIG. 6, all of the light emitting diode devices are connected in a single array where the light emitting diode devices are in both parallel and serial relationship. Each of the light emitting diode devices in a serial string are of the same color. Thus, for example, a monolithic device 70 may include three sets of serial strings that are connected in parallel where a first set of serial strings 72 corresponds to light emitting diode devices with a first phosphor (e.g, green), a second set of serial strings of light emitting diode devices 76 corresponds to light emitting diode devices with no phosphor (e.g., blue) and a third set of serial strings of light emitting diode devices 74 corresponds to light emitting diode devices with a second phosphor (e.g, red).

In the case of the circuit of FIG. 6, if one of the light emitting diode devices in a serial string of the array fails by going open circuit, the other light emitting diode devices in that level of the array will handle the extra current and, at least partially, compensate for the failed light emitting diode device. However, because the light emitting diode devices at the same level of the array are not all the same color as the failed light emitting diode device and the current through them each increase, there may be a change in the relative contributions of the individual color components to the overall color of the output of the device. In the case of a light emitting diode device failing by becoming a short circuit, then an entire level of the array will be bypassed and, as long as the level has the same overall proportion of the different colors, the remaining light emitting diode devices will continue to output light in the same relative proportions and the color may not change.

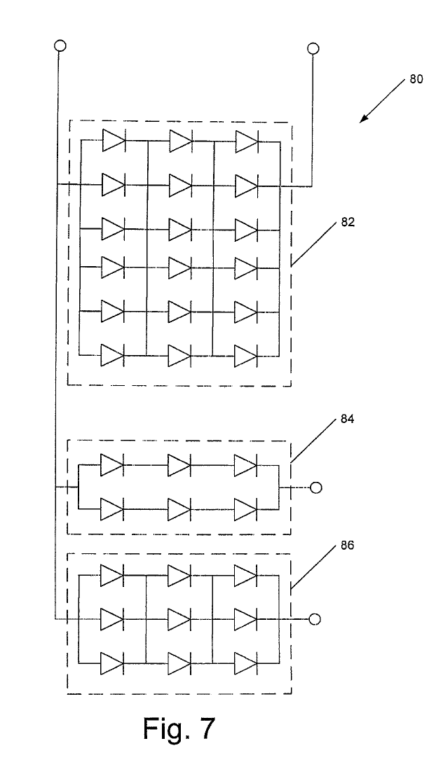

FIG. 7 is a further alternative electrical interconnection where individual sub-arrays may be driven separately from a common input. Alternatively, a common output could be provided and separate inputs for the various sub-arrays could be provided. As seen in FIG. 7, each color within a device may be electrically connected as sub-arrays of light emitting diode devices that are in both parallel and serial relationship. These sub-arrays may then be connected to an input in parallel such that an n+1 terminal device is provided, where n is the number of colors. Thus, for example, a monolithic device 80 may include three sub-arrays of light emitting diode devices where a first sub-array 82 corresponds to light emitting diode devices with a first phosphor (e.g, green), a second sub-array of light emitting diode devices 84 corresponds to light emitting diode devices with no phosphor (e.g., blue) and a third sub-array of light emitting diode devices 86 corresponds to light emitting diode devices with a second phosphor (e.g, red).

In the case of the circuit of FIG. 7, if one of the light emitting diode devices in a sub-array fails by going open circuit, the other light emitting diode devices in that level of the sub-array will handle the extra current and, at least partially, compensate for the failed light emitting diode device. In the case of a light emitting diode device failing by becoming a short circuit, then the individual control of the sub-array may compensate for the change in Vf by separately controlling the sub-array.

As described above, in some embodiments where there are a plurality of lumiphors, the lumiphors can all be similar to each other, or one or more of the lumiphors can differ from other lumiphors (or from another lumiphor) in its/their respective luminescent material(s), in its/their respective lumiphor concentrations (i.e., amount of luminescent material(s) per unit surface area or unit volume), in its/their respective shapes, and/or in its/their respective sizes. Such embodiments can have any desired circuitry, e.g., circuitry as shown in FIG. 7 with individual sub-arrays for different light colors being output and with different lumiphors (which output respective different light colors) being provided in different amounts, different shapes and/or different sizes, if desired.

The present inventive subject matter encompasses embodiments which comprise a monolithic die and a plurality of lumiphors, in which the die comprises a plurality of solid state light emitting devices, and in which at least one of the lumiphors differs from one or more other lumiphors in its/their respective luminescent material(s), in its/their respective lumiphor concentrations (i.e., amount of luminescent material(s) per unit surface area or unit volume), in its/their respective shapes, and/or in its/their respective sizes, and in which two or more groups of solid state light emitting devices (each group comprising one or more solid state light emitting devices) are separately controllable, whereby different and/or variable voltages can be applied to the separately controllable groups of solid state light emitting devices in order to maintain a substantially constant output color (e.g., where the relative intensity of one or more of the solid state light emitting devices changes, and such change can thus be compensated for) and/or in order to alter the output color. For instance, the present inventive subject matter encompasses an embodiment which comprises a monolithic die, a pattern of first lumiphors (each of which includes a first concentration of a first luminescent material which emits greenish-yellowish light), a pattern of second lumiphors (each of which includes a second concentration of the first luminescent material, the second concentration being larger than the first concentration) and a pattern of third lumiphors (each of which includes a third concentration of a second luminescent material which emits red light), the monolithic die comprises a plurality of solid state light emitting devices, each of which emits blue light, and where different groups of solid state light emitting devices (each group including at least one solid state light emitting device) are separately controllable such that different current and/or voltage can be applied to such different groups of solid state light emitting devices, and the separately controllable groups of solid state light emitting devices are aligned with the respective different patterns of lumiphors (or the separately controllable groups of solid state light emitting devices are aligned with differing aggregate percentages of the surface areas different patterns of lumiphors), such that the color coordinates of the light being output can be adjusted by adjusting the relative power supplied to the respective separately controllable solid state light emitting devices and/or different groups of solid state light emitting devices (e.g., to change the color temperature of emitted white light, to maintain the same color temperature despite other changes which would otherwise cause the output light color coordinates to drift, etc.) (for instance, if a first group of solid state light emitting devices is aligned with 60% of the first lumiphors, 40% of the second lumiphors and 20% of the third lumiphors, a second group of solid state light emitting devices is aligned with the remaining 40% of the first lumiphors, the remaining 60% of the second lumiphors and 20% of the third lumiphors, and a third group of solid state light emitting devices is aligned with the remaining 60% of the third lumiphors, adjusting the respective currents supplied to the first, second and third groups of solid state light emitting devices will alter the color output by the light emitter (i.e., the output light will have different color coordinates—for example, the color temperature of the output light could be adjusted from 2700 K to 3500 K). Similarly, the present inventive subject matter encompasses devices as describe in the preceding sentence, except that at least part of the pattern of third lumiphors (each of which includes a third concentration of a second luminescent material which emits red light) is replaced with one or more solid state light emitting devices (e.g., light emitting diodes), e.g., in this case, which emit red light.

While each of the above electrical interconnects has been described with reference to strings of the same color output, strings of mixed color outputs could also be provided. Furthermore, a device with no common input or output for sub-arrays could also be provided such that different input voltages could be provided and the sub-array could also be separately controlled.

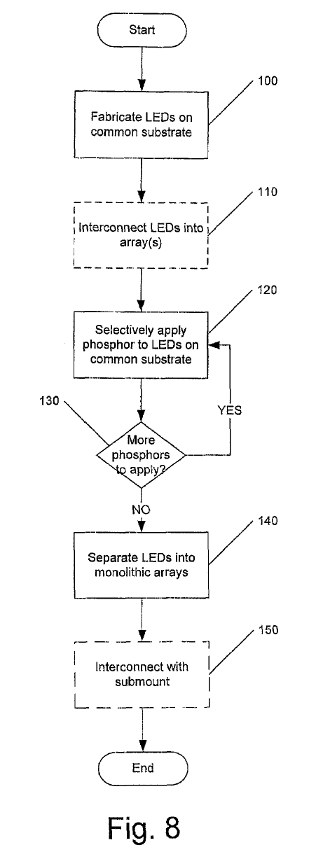

FIG. 8 is a flowchart illustrating fabrication of light emitters according to some embodiments of the present inventive subject matter. As seen in FIG. 8. light emitting diode devices are fabricated on a common substrate (block 100). The light emitting diode devices are divided into individual solid state light emitting devices that may be separately electrically interconnected. The individual solid state light emitting devices may be provided by any suitable technique for defining the individual light emitting diode devices. For example, trench isolation and/or ion implantation to make the implanted regions semi-insulating or insulating may be used to define the peripheries and electrically isolate the active regions of the individual solid state light emitting devices.

The substrate may also be thinned, laser patterned, etched or subjected to chemical mechanical polishing (CMP). For example, light extraction features may also be provided on the substrate to improve extraction of light through the substrate. In particular embodiments, the light extraction features approximate a “moth eye” structure. In other embodiments, other light extraction features may also be provided. Various light extraction features are known to those of skill in the art. Techniques for patterning the substrate for light extraction are also known to those of skill in the art.

Optionally, the solid state light emitting devices may be electrically interconnected on the substrate (block 110). Such interconnection may be carried out as described in the above-referenced United States patent applications.

A phosphor or other luminous material is selectively applied to the light extraction region of the solid state light emitting device on the substrate (block 120). Such a selective application may be provided, for example, by ink-jet or bubble-jet printing the phosphor on the light extraction region of the solid state light emitting device. Similarly, masking and blanket deposition could also be utilized. Techniques for the selective application of luminous materials are known to those of skill in the art and any such technique may be utilized.

After application of the phosphor, if additional phosphors are to be applied (block 130), then the selective application of the phosphor may be repeated for the next set of light emitting diode devices and/or luminescent material (block 120). If all phosphors have been applied (block 130), the isolated solid state light emitting devices are separated from the wafer (block 140) to provide a monolithic die that includes a plurality of solid state light emitting devices. This separation process may, for example, be carried out by sawing, scoring and breaking or other techniques known to those of skill in the art for separating solid state light emitting devices within a wafer.

Optionally, some or all of the electrical interconnection of light emitting diode devices may be carried out by mounting the singulated monolithic devices on a submount (block 150).

The submount may be as described in commonly assigned and concurrently filed U.S. patent application Ser. No. ______ entitled ILLUMINATION DEVICES USING INTERCONNECTED ARRAYS OF LIGHT EMITTING DEVICES, AND METHODS OF FABRICATING SAME (Attorney Docket No. 931_{—}078 NP; Inventors: Gerald H. Negley and Antony Paul van de Ven), as well as U.S. Patent Application Ser. No. 60/986,795 entitled ILLUMINATION DEVICES USING INTERCONNECTED ARRAYS OF LIGHT EMITTING DEVICES, AND METHODS OF FABRICATING SAME, filed Nov. 9, 2007 (Attorney Docket No. 931_{—}078 PRO2), and U.S. Patent Application No. 60/982,909, filed on Oct. 26, 2007 (attorney docket no. 931_{—}078 PRO). The resulting light emitting device may also be packaged as described herein to provide a packaged light emitting device.

While the operations illustrated in FIG. 8 are described with reference to a linear step-wise process, operations may be performed in parallel or out of turn as long as the overall operations achieve the desired result of providing a monolithic light emitter having a plurality of luminous materials provided thereon. For example, the selective application of phosphor operations illustrated in FIG. 8 may be performed before or after the monolithic collection of devices are separated from the wafer. Thus, embodiments of the present inventive subject matter should not be construed as limited to the particular sequence of operations illustrated in FIG. 8.

Furthermore, while operations of FIG. 8 are described with reference to a monolithic light emitter comprising multiple solid state light emitting devices, such operations could be appropriately modified to provide for the selective application of one or more lumiphor on a single light emitting device. For example, the operations of block 100 could be replaced by fabrication of the single light emitting device. Likewise, the operations of blocks 110 and 150 may be omitted. Furthermore, block 120 may be modified to selectively apply a phosphor on a selected area of the single device, the selected area being less than all of the area of the device.

Additionally, while the operations of FIG. 8 are described as taking place primarily before singulation of the devices from the wafer, such operations could take place after separation of the wafer into individual devices. Thus, embodiments of the present inventive subject matter should not be limited to the particular sequence of operations illustrated in FIG. 8 but may include any sequence that provides devices as described herein.

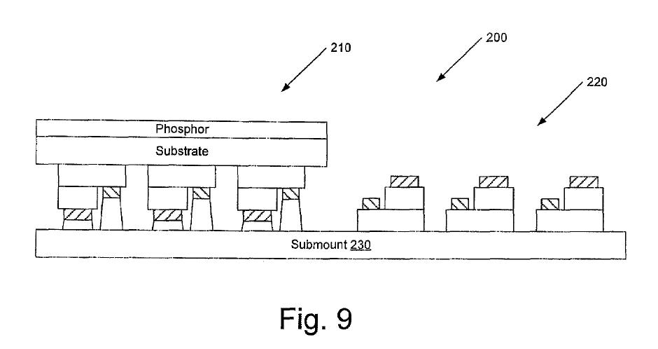

FIG. 9 illustrates a further example of possible embodiments of the present inventive subject matter where a submount with light emitting elements is utilized to provide a device 200 having multiple color emissions. In the embodiments illustrated in FIG. 9, a submount 230 includes an array of light emitting diodes of one color 220 and a region of interconnects onto which is attached a monolithic array of light emitting diodes of another color 210. The submount 230 may also include a region of transistors and diodes and components to form part or all of a power supply or control circuit. For example, the submount 230 may comprise a GaAs or GaP layer with regions, such regions being delineated areas, including a region comprising layers of AlAs or AlInGaP or AlGaAs forming red orange or yellow light emitting diodes or arrays of diodes and interconnected. Preferably, another region(s) where a monolithic array (or arrays) of blue and/or green and or cyan and or yellow light emitting diodes can be mounted. The mounted light emitting diode devices and/or the light emitting diode devices on the submount may have selectively applied phosphors as described above. Such multiple light emitting diode device light emitters are described in further detail in commonly assigned and concurrently filed U.S. patent application Ser. No. ______ entitled ILLUMINATION DEVICES USING INTERCONNECTED ARRAYS OF LIGHT EMITTING DEVICES, AND METHODS OF FABRICATING SAME (Attorney Docket No. 931_{—}078 NP; Inventors: Gerald H, Negley and Antony Paul van de Ven), as well as U.S. Patent Application Ser. No. 60/986,795 entitled ILLUMINATION DEVICES USING INTERCONNECTED ARRAYS OF LIGHT EMITTING DEVICES, AND METHODS OF FABRICATING SAME, filed Nov. 9, 2007 (Attorney Docket No. 931_{—}078 PRO2), and U.S. Patent Application No. 60/982,909, filed on Oct. 26, 2007 (attorney docket no. 931_{—}078 PRO).

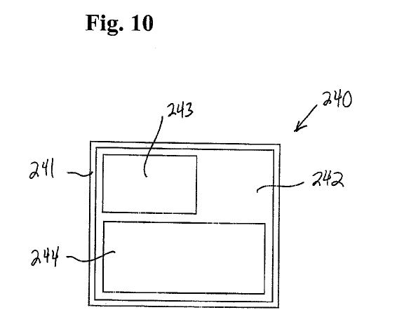

FIG. 10 depicts a further embodiment of a light emitter according to the present inventive subject matter. Referring to FIG. 10, there is shown a light emitter 240 comprising a monolithic die 241 including a single solid state light emitting device 242, a first pattern of a first lumiphor 243 on the die 241, and a second pattern of a second lumiphor 244 on the die 241. The first lumiphor 243 covers less than all of the light emission region of the monolithic die 241 such that a portion of light emitted by the solid state light emitting device 242 is directed into the first lumiphor 243 and a portion of light emitted by the solid state light emitting device 242 is not directed into the first lumiphor 243. Likewise, the second lumiphor 244 covers less than all of the light emission region of the monolithic die 241 such that a portion of light emitted by the solid state light emitting device 242 is directed into the second lumiphor 244 and a portion of light emitted by the solid state light emitting device 242 is not directed into the second lumiphor 244. A third portion of light emitted by the solid state light emitting device is not directed into any lumiphor.

The present inventive subject matter also encompasses light emitters which have a plurality of solid state light emitting devices, each having one or more lumiphors, (i.e., a light emitter which has a plurality of structures as shown in FIG. 10, except that adjacent to each light emitting device, the number of lumiphors, the relative size(s) of the lumiphor or each of the lumiphors, the shape(s) of the lumiphor or each of the lumiphors, the position(s) of the lumiphor(s), the type(s) of luminescent material contained in the lumiphor or each individual lumiphor, the concentration of lumiphor(s) in the lumiphor or each individual lumiphor, and the arrangement of the lumiphor(s) can, if desired, be individually selected, or such properties for respective groups of lumiphors can be selected). That is, the respective luminescent materials, lumiphor sizes, number of lumiphors, lumiphor positioning, luminescent material concentration and/or lumiphor arrangement adjacent to different solid state light emitting devices can be similar to one another, different from one another, or combinations thereof.

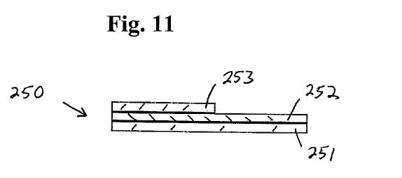

FIG. 11 depicts a further embodiment of a light emitter according to the present inventive subject matter. Referring to FIG. 11, there is shown a light emitter 250 comprising a monolithic die 251, a first pattern of a first lumiphor 252 on the die, and a second pattern of a second lumiphor 253 on the die. When the light emitter 250 emits light, a first portion of light emitted by the light emitter passes through both the first lumiphor 251 and the second lumiphor 252 (some or all of which is converted in the first lumiphor 251, in the second lumiphor 252, or in both the first lumiphor and the second lumiphor), and a second portion of light emitted by the light emitter 250 passes through the first lumiphor 252 (in which some or all of the light is converted) and does not pass through (i.e., escapes without coming into contact with) the second lumiphor 253.

While embodiments of the present inventive subject matter have been described with reference to a multi-quantum well structure, the present inventive subject matter may be utilized with any suitable light emitting diode device configuration. Furthermore, light extraction enhancements, such as internal reflecting layers, transparent ohmic contacts and the like may be utilized to improve light extraction from the individual light emitting diode devices. Accordingly, embodiments of the present inventive subject matter should not be construed as limited to a particular light emitting diode device configuration but may be used with any configuration capable of being mounted to a submount for electrical interconnection to provide a high voltage monolithic light emitter.

The light emitters of the present inventive subject matter can be supplied with electricity in any desired manner. Skilled artisans are familiar with a wide variety of power supplying apparatuses, and any such apparatuses can be employed in connection with the present inventive subject matter. The light emitters of the present inventive subject matter can be electrically connected (or selectively connected) to any desired power source, persons of skill in the art being familiar with a variety of such power sources.

Light emitters as described herein may be incorporated into a lighting device. The expression “lighting device”, as used herein, is not limited, except that it is capable of emitting light. That is, a lighting device can be a device which illuminates an area or volume, e.g., a structure, a swimming pool or spa, a room, a warehouse, an indicator, a road, a parking lot, a vehicle, signage, e.g., road signs, a billboard, a ship, a toy, a mirror, a vessel, an electronic device, a boat, an aircraft, a stadium, a computer, a remote audio device, a remote video device, a cell phone, a tree, a window, an LCD display, a cave, a tunnel, a yard, a lamppost, or a device or array of devices that illuminate an enclosure, or a device that is used for edge or back-lighting (e.g., back light poster, signage, LCD displays), bulb replacements (e.g., for replacing AC incandescent lights, low voltage lights, fluorescent lights, etc.), lights used for outdoor lighting, lights used for security lighting, lights used for exterior residential lighting (wall mounts, post/column mounts), ceiling fixtures/wall sconces, under cabinet lighting, lamps (floor and/or table and/or desk), landscape lighting, track lighting, task lighting, specialty lighting, ceiling fan lighting, archival/art display lighting, high vibration/impact lighting—work lights, etc. mirrors/vanity lighting, or any other light emitting device.

The present inventive subject matter further relates to an illuminated enclosure (the volume of which can be illuminated uniformly or non-uniformly), comprising an enclosed space and at least one lighting device according to the present inventive subject matter, wherein the lighting device illuminates at least a portion of the enclosure (uniformly or non-uniformly).

The present inventive subject matter is further directed to an illuminated area, comprising at least one item, e.g., selected from among the group consisting of a structure, a swimming pool or spa, a room, a warehouse, an indicator, a road, a parking lot, a vehicle, signage, e.g., road signs, a billboard, a ship, a toy, a mirror, a vessel, an electronic device, a boat, an aircraft, a stadium, a computer, a remote audio device, a remote video device, a cell phone, a tree, a window, an LCD display, a cave, a tunnel, a yard, a lamppost, etc., having mounted therein or thereon at least one lighting device as described herein.

The expression “illumination” (or “illuminated”), as used herein when referring to a solid state light emitter, means that at least some current is being supplied to the solid state light emitter to cause the solid state light emitter to emit at least some light. The expression “illuminated” encompasses situations where the solid state light emitter emits light continuously or intermittently at a rate such that a human eye would perceive it as emitting light continuously, or where a plurality of solid state light emitters of the same color or different colors are emitting light intermittently and/or alternatingly (with or without overlap in “on” times) in such a way that a human eye would perceive them as emitting light continuously (and, in cases where different colors are emitted, as a mixture of those colors).

Furthermore, while certain embodiments of the present inventive subject matter have been illustrated with reference to specific combinations of elements, various other combinations may also be provided without departing from the teachings of the present inventive subject matter. Thus, the present inventive subject matter should not be construed as being limited to the particular exemplary embodiments described herein and illustrated in the Figures, but may also encompass combinations of elements of the various illustrated embodiments.

Many alterations and modifications may be made by those having ordinary skill in the art, given the benefit of the present disclosure, without departing from the spirit and scope of the inventive subject matter. Therefore, it must be understood that the illustrated embodiments have been set forth only for the purposes of example, and that it should not be taken as limiting the inventive subject matter as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive subject matter.

Any two or more structural parts of the devices described herein can be integrated. Any structural part of the devices described herein can be provided in two or more parts (which are held together, if necessary). Similarly, any two or more functions can be conducted simultaneously, and/or any function can be conducted in a series of steps.

That which is claimed is:

1. A light emitter, comprising:
a monolithic die comprising at least one solid state light emitting device; and
at least a first lumiphor on the die, the first lumiphor covering less than all of a light emission region of the monolithic die such that a first portion of light emitted by the at least one solid state light emitting device is directed into the first lumiphor and a second portion of light emitted by the at least one solid state light emitting device is not directed into the first lumiphor.

2. The light emitter of claim 1, further comprising:
at least a second lumiphor on the die, the second lumiphor being substantially non-overlapping with the first lumiphor such that the first portion of light is not directed into the second lumiphor.

3. The light emitter of claim 2, wherein the first lumiphor comprises a first luminescent material and the second lumiphor comprises a second luminescent material, the second luminescent material differing from the first luminescent material.

4. The light emitter of claim 2, wherein the first lumiphor is in a first shape and the second lumiphor is in a second shape, the second shape differing from the first shape.

5. The light emitter of claim 2, wherein the first lumiphor comprises a luminescent material in a first concentration and the second lumiphor comprises a luminescent material in a second concentration, the second concentration differing from the first concentration.

6. The light emitter of claim 5, wherein the first lumiphor comprises a first luminescent material and the second lumiphor comprises a second luminescent material, the second luminescent material differing from the first luminescent material.

7. The light emitter of claim 2, wherein the first lumiphor is of a first size and the second lumiphor is of a second size, the second size differing from the first size.

8. The light emitter of claim 1, further comprising:
at least a second lumiphor on the die, at least a portion of the second lumiphor overlapping at least a portion of the first lumiphor such that at least part of the first portion of light is also directed into the second lumiphor.

9. The light emitter of claim 8, wherein the first lumiphor comprises a first luminescent material and the second lumiphor comprises a second luminescent material, the second luminescent material differing from the first luminescent material.

10. The light emitter of claim 1, wherein the first lumiphor is part of a first lumiphor pattern comprising a first plurality of lumiphors, each of the first plurality of lumiphors comprising a first luminescent material.

11. The light emitter of claim 10, wherein the second lumiphor is part of a second lumiphor pattern comprising a second plurality of lumiphors, each of the second plurality of lumiphors comprising a second luminescent material.

12. The light emitter of claim 11, wherein each of the first plurality of lumiphors is substantially non-overlapping with each of the second plurality of lumiphors.

13. The light emitter of claim 11, wherein each of the first plurality of lumiphors overlaps at least a portion of at least one of the second plurality of lumiphors.

14. The light emitter of claim 2, wherein:
a third portion of light emitted by the at least one solid state light emitting device is directed into the second lumiphor,
the third potion of light emitted by the at least one solid state light emitting device die is not directed into the first lumiphor and,
the second portion of light is not directed into the second lumiphor.

15. The light emitter of claim 1, wherein the at least one solid state light emitting device consists of a single solid state light emitting device.

16. The light emitter of claim 1, wherein the at least one solid state light emitting device comprises a plurality of solid state light emitting devices on a common substrate.

17. The light emitter of claim 1, wherein the at least one solid state light emitting device comprises one or more light emitting diode devices.

18. A light emitter comprising:
a monolithic die comprising a plurality of solid state light emitting devices on a common substrate;
a first lumiphor on a first group of the plurality of solid state light emitting devices, the first group being less than all of the plurality of solid state light emitting devices; and
an electrical interconnection to electrically connect respective ones of the plurality of solid state light emitting devices.

19. The light emitter of claim 18, wherein the electrical interconnection connects the plurality of solid state light emitting devices into an array of serially-connected subsets of parallel-connected solid state light emitting devices.

20. The light emitter of claim 19, further comprising a second lumiphor on a second group of the plurality of solid state light emitting devices, the second group of solid state light emitting devices and the first group of solid state light emitting devices being mutually exclusive.

21. The light emitter of claim 20, wherein the second group and the first group together comprise all of the plurality of solid state light emitting devices on the common substrate.

22. The light emitter of claim 19, further comprising a second lumiphor, the second lumiphor at least partially overlapping the first lumiphor.

23. The light emitter of claim 19, wherein the first group of the plurality of solid state light emitting devices are separately connected as a first array of serially-connected subsets of parallel-connected solid state light emitting devices and remaining ones of the plurality of solid state light emitting devices are connected as at least a second array of serially-connected solid state light emitting devices.

24. The light emitter of claim 23, wherein the first group and the second group are electrically connected in parallel.

25. The light emitter of claim 23, wherein the first group and the second group are electrically connected so as to be separately controllable.

26. The light emitter of claim 23, wherein the first group of solid state light emitting devices are dispersed throughout the plurality of solid state light emitting devices.

27. The light emitter of claim 18, wherein the light emitter produces light that is perceived as white when current flows through the plurality of solid state light emitting devices.

28. A light emitter, comprising:
a monolithic die comprising a plurality of solid state light emitting devices on a common substrate;
an electrical interconnection to electrically connect respective ones of the plurality of solid state light emitting devices; and
a plurality of unit cells, each unit cell comprising a group of the plurality of solid state light emitting devices, each of the unit cells comprising a first lumiphor on less than all of the group of solid state light emitting devices in the unit cell.

29. The light emitter of claim 28, wherein each of the unit cells further comprises a second lumiphor, different from the first lumiphor, on solid state light emitting devices in the unit cell other than solid state light emitting devices on which the first lumiphor is provided.

30. The light emitter of claim 28, wherein each of the unit cells further comprises a second lumiphor, different from the first lumiphor, the second lumiphor at least partially overlapping the first lumiphor.

31. The light emitter of claim 29, wherein each of the unit cells further comprises a third lumiphor, different from the first and the second lumiphors, on solid state light emitting devices in the unit cell other than solid state light emitting devices on which the first lumiphor is provided or solid state light emitting devices on which the second lumiphor is provided.

32. The light emitter of claim 28, wherein solid state light emitting devices in the plurality of unit cells are electrically connected in an array of serially-connected subsets of solid state light emitting devices, each of the subsets comprising a plurality of solid state light emitting diodes that are electrically connected in parallel.

33. The light emitter of claim 32, wherein solid state light emitting devices on which the first phosphor is provided are electrically connected in parallel in the serially-connected subsets with solid state light emitting devices on which the first phosphor is not provided.

34. The light emitter of claim 28, wherein light produced by the light emitter is perceived as white light.

35. A method of fabricating a light emitter, comprising:
selectively applying at least one lumiphor to a monolithic die comprising a plurality of solid state light emitting devices, so as to cover only a portion of the die.

36. The method of claim 35, wherein selectively applying at least one lumiphor comprises selectively applying a plurality of lumiphors in substantially non-overlapping portions of the die.

37. The method of claim 35, wherein selectively applying at least one lumiphor comprises selectively applying a plurality of lumiphors in at least partially overlapping portions of the die.

38. The method of claim 36, wherein at least one portion of the die does not have a lumiphor thereon.

39. A method of fabricating a light emitter, comprising:
selectively applying at least one lumiphor on selected ones of a plurality of solid state light emitting devices on a common substrate, the selected ones comprising less than all of the plurality of solid state light emitting devices.

40. The method of claim 39, wherein selectively applying at least one lumiphor comprises:
applying a first lumiphor on a first group of the plurality of solid state light emitting devices; and
applying a second lumiphor on a second group of the plurality of solid state light emitting devices, the second group and the first group being mutually exclusive.

41. The method of claim 39, wherein selectively applying at least one lumiphor comprises:
applying a first lumiphor on a first group of the plurality of solid state light emitting devices; and
applying a second lumiphor on a second group of the plurality of solid state light emitting devices, at least some of the solid state light emitting devices in the second group also being in the first group.

42. The method of claim 39, wherein selectively applying comprises selectively applying a plurality of lumiphors in a repeating pattern of unit cells of lumiphors on the plurality of solid state light emitting devices, the unit cells including at least one solid state light emitting device on which each of the plurality of lumiphors is provided.

43. The method of claim 39, further comprising electrically connecting the plurality of solid state light emitting devices in an array of serially-connected subsets of parallel-connected solid state light emitting devices.

44. A light emitter, comprising:
a monolithic die comprising at least one solid state light emitting device;
at least a first lumiphor on the die; and
at least a second lumiphor on the die,
wherein:
a first portion of light emitted by the at least one solid state light emitting device passes through both the first lumiphor and the second lumiphor, and
a second portion of light emitted by the at least one solid state light emitting device passes through the first lumiphor and does not pass through the second lumiphor.

45. The light emitter of claim 44, wherein the first lumiphor is part of a first lumiphor pattern comprising a first plurality of lumiphors, each of the first plurality of lumiphors comprising a first luminescent material.

46. The light emitter of claim 45, wherein the second lumiphor is part of a second lumiphor pattern comprising a second plurality of lumiphors, each of the second plurality of lumiphors comprising a second luminescent material.

47. A method of fabricating a light emitter, comprising:
selectively applying at least a first lumiphor on a monolithic die comprising at least one solid state light emitting device, the first lumiphor covering less than all of a light emission region of the monolithic die, to form an initial emitter;
measuring a light output from the initial emitter; and
selectively applying at least a second lumiphor on the monolithic die to form the light emitter.

48. The method of claim 47, wherein the first lumiphor comprises a second luminescent material, the second lumiphor comprises a second luminescent material, and the first luminescent material differs from the second luminescent material.
